(19) United States
(12) Patent Application Publication
(10) Pub. No.: US 2018/0193886 A1
(43) Pub. Date: Jul. 12, 2018

(54) SUBSTRATE PROCESSING METHOD AND SUBSTRATE PROCESSING APPARATUS

(71) Applicant: SCREEN Holdings Co., Ltd., Kyoto (JP)

(72) Inventors: Hiroshi ABE, Kyoto (JP); Manabu OKUTANI, Kyoto (JP); Naohiko YOSHIHARA, Kyoto (JP)

(21) Appl. No.: 15/849,794

(22) Filed: Dec. 21, 2017

(30) Foreign Application Priority Data
Jan. 12, 2017 (JP) 2017-003512

(51) Int. Cl. B08B 7/00; H01L 21/02; H01L 21/67; H01L 21/687; B08B 3/08; B08B 3/10

(52) U.S. Cl. CPC B08B 7/0014; H01L 21/02057; H01L 21/67034; B08B 2203/007; H01L 21/68714; B08B 3/08; B08B 3/106; H01L 21/67167

(57) ABSTRACT

A substrate processing method includes a substrate holding step that a substrate is held by a substrate holding unit that holds the substrate horizontally, a sealing step of sealing an internal space of a chamber in a state where the substrate holding unit that holds the substrate is housed in the internal space of the chamber, a liquid film forming step of forming a liquid film of processing liquid, which processes an upper surface of the substrate, by supplying the processing liquid to the upper surface of the substrate which is held horizontally, a pressurizing step of pressurizing the internal space until a pressure of the internal space reaches a first pressure which is higher than an atmospheric pressure, by supplying a gas to the internal space, a heating step of heating the substrate such that a vapor layer of processing liquid is formed between the liquid film and the substrate in a state where the pressure of the internal space reaches the first pressure, and a liquid film excluding step of excluding the liquid film from the substrate by evaporating the processing liquid, by reducing the pressure of the internal space until the pressure of the internal space reaches a second pressure, which is lower than the first pressure, while keeping a state where the vapor layer of the processing liquid between the liquid film and the substrate is formed.

### BACKGROUND OF THE INVENTION

### 1. Field of the Invention

The present invention relates to a substrate processing method and a substrate processing apparatus for processing a substrate. Examples of substrates to be processed include semiconductor wafers, substrates for liquid crystal displays, substrates for FPD (Flat Panel Display) for organic EL (Electroluminescence) display device, substrates for optical disks, substrates for magnetic disks, substrates for magneto-optical disks, substrates for photomasks, ceramic substrates, substrates for solar cells, etc.

### 2. Description of the Related Art

In substrate processing performed by a single substrate processing type substrate processing apparatus that processes a substrate one by one, for example, a chemical solution is supplied to the substrate that is held substantially horizontally by means of a spin chuck. Thereafter, a rinse liquid is supplied to the substrate, and the chemical solution on the substrate is thereby replaced with the rinse liquid. Thereafter, a spin drying step is performed to remove the rinse liquid on the substrate.

When a fine pattern is formed on a front surface of the substrate as shown in FIG. 11, there is a possibility that the rinse liquid that has entered the inside of the pattern cannot be eliminated in the spin drying step. As a result, there is a possibility that a drying failure will occur. A liquid surface (an interface between air and liquid) of the rinse liquid that has entered the inside of the pattern is formed in the inside of the pattern, the surface tension of the liquid thus acts on contact positions between the liquid surface and the pattern. If the surface tension is high, the pattern collapse will occur easily. Water, which is a typical rinse liquid, is high in surface tension, the pattern collapse in the spin drying step can thus not be ignored.

Therefore, a method in which isopropyl alcohol (IPA), which is an organic solvent having lower surface tension than water, is supplied, has been proposed. The water that has entered the inside of the pattern is replaced with IPA by processing the upper surface of the substrate by IPA. Thereafter, the upper surface of the substrate is dried by removing the IPA.

However, in recent years, a fine pattern (columnar pattern, linear pattern, etc.) that is very small and that has a high aspect ratio has been formed on a front surface of the substrate in order to realize high integration. The fine pattern that is very small and has high aspect ratio is liable to collapse. When the IPA that is in the inside of the fine pattern is gradually evaporated from above, the surface tension continues to act on contact positions between the liquid surface of the IPA and the fine pattern until the IPA is completely evaporated. Therefore, there is a possibility that the pattern collapse will occur. Therefore, it is necessary to shorten the time during which the surface tension acts on the fine pattern after the formation of a liquid film of IPA on the upper surface of the substrate.

Therefore, in the specification of United States Patent Application Publication No. 2014/127908, a substrate processing method in which the substrate is heated by a heater, has been proposed. A vapor layer is formed between the liquid film of IPA and the upper surface of the substrate by heating the substrate by the heater. As a result, the inside of the fine pattern is filled by a gas phase IPA. Therefore, the time during which the liquid surface of the IPA generates inside of the fine pattern, can be shortened. Compared to the method in which the IPA which is inside of the fine pattern is evaporated from above, the time during which the surface tension acts on the fine pattern can thus be shortened.

### SUMMARY OF THE INVENTION

In the substrate processing method described in the specification of United States Patent Application Publication No. 2014/127908, the liquid film of IPA is excluded outside of the substrate in the state where the vapor layer of the IPA is formed between the liquid film of the IPA and the upper surface of the substrate. In the specification of United States Patent Application Publication No. 2014/127908, for example, a method (see FIG. 11A to FIG. 11C of United States Patent Application Publication No. 2014/127908) of tilting the substrate to slide off the liquid film of IPA, a method (see FIG. 12A to FIG. 12C of United States Patent Application Publication No. 2014/127908) of excluding the liquid film of the IPA by absorbing the liquid film of the IPA by absorbing nozzle, and the like are disclosed as the method of excluding the liquid film of IPA in the state where the vapor layer is formed.

The method of excluding the liquid film of the IPA outside of the substrate in the state where the vapor layer of the IPA is formed between the liquid film of the IPA and the upper surface of the substrate, is preferable to be selectable according to the configuration of the substrate processing apparatus or the like.

Therefore, one object of the present invention is, in a configuration in which a vapor layer is formed between a liquid film of a processing liquid such as IPA or the like and an upper surface of a substrate, to provide a substrate processing method and a substrate processing apparatus that can exclude a liquid film from a substrate excellently.

The one preferred embodiment of the present invention provides a substrate processing method including a substrate holding step that a substrate is held by a substrate holding unit that holds the substrate horizontally, a sealing step of sealing an internal space of a chamber in a state where the substrate holding unit that holds the substrate is housed in the internal space of the chamber, a liquid film forming step of forming a liquid film of processing liquid, which processes an upper surface of the substrate, by supplying the processing liquid to the upper surface of the substrate which is held horizontally, a pressurizing step of pressurizing the internal space until a pressure of the internal space reaches a first pressure which is higher than an atmospheric pressure, by supplying a gas to the internal space, a heating step of heating the substrate such that a vapor layer of processing liquid is formed between the liquid film and the substrate in a state where the pressure of the internal space reaches the first pressure, and a liquid film excluding step of excluding the liquid film from the substrate by evaporating the processing liquid, by reducing the pressure of the internal space until the pressure of the internal space reaches a second pressure, which is lower than the first pressure, while keeping a state where the vapor layer of the processing liquid between the liquid film and the substrate is formed.

According to this method, in the heating step, the substrate is heated so as to reach high temperature at which the vapor layer is formed between the liquid film and the substrate. Therefore, the vapor layer is formed between the liquid film and the substrate by evaporating the processing liquid near the upper surface of the substrate. Therefore, compared to a method of evaporating the processing liquid of the liquid film gradually from above, the time during which the surface tension acts on the upper surface of the substrate is shortened.

In depressurization of the internal space in the liquid film excluding step, the pressure of the internal space is brought to the second pressure which is lower than the first pressure in a state where the vapor layer is maintained. Incidentally, the aforementioned high temperature, at which the vapor layer is formed, is a temperature which is higher than a boiling point at the second pressure. Therefore, the temperature of the liquid film is higher than the boiling point in a state where the pressure of the internal space reaches the second pressure by depressurization. Therefore, the processing liquid is instantaneously evaporated, so that the liquid film is instantaneously excluded from the substrate.

As a result, in a configuration in which the vapor layer is formed between the liquid film of the processing liquid and the upper surface of the substrate, the liquid film is excellently excluded from the substrate.

The one preferred embodiment of the present invention provides a substrate processing method including a substrate holding step that a substrate is held by a substrate holding unit that holds the substrate horizontally, a sealing step of sealing an internal space of a chamber in a state where the substrate holding unit that holds the substrate is housed in the internal space of the chamber, a liquid film forming step of fainting a liquid film of processing liquid, which processes an upper surface of the substrate, by supplying the processing liquid to the upper surface of the substrate which is held horizontally, a pressurizing step of pressurizing the internal space until a pressure of the internal space reaches a first pressure which is higher than an atmospheric pressure, by supplying a gas to the internal space, a heating step of heating the substrate such that the temperature of the liquid film reaches a temperature which is higher than a boiling point of the processing liquid at the atmospheric pressure in a state where the pressure of the internal space reaches the first pressure, and a liquid film excluding step of excluding the liquid film from the substrate by evaporating the processing liquid so as to pass through a state where the vapor layer of the processing liquid between the liquid film and the substrate is formed, by reducing the pressure of the internal space until the pressure of the internal space reaches a second pressure, which is lower than the first pressure, while keeping a state where the temperature of the liquid film reaches the boiling point of the processing liquid at the atmospheric pressure.

According to this method, in the liquid excluding step, by reducing the pressure of the sealed internal space of the chamber, the liquid film is excluded from the substrate after passing through the state in which the vapor layer is formed. The temperature of the substrate reaches a high temperature at which the vapor layer is formed between the liquid film and the substrate during depressurization process of the internal space. Therefore, the processing liquid near the upper surface of the substrate is instantaneously evaporated, and the vapor layer is formed between the liquid film and the substrate. Therefore, compared to the method of evaporating the processing liquid of the liquid film gradually from above, the time during which the surface tension acts on the upper surface of the substrate is shortened.

In depressurization of the internal space in the liquid film excluding step, the pressure of the internal space is brought to the second pressure, which is lower than the first pressure, in a state where the temperature of the liquid film is maintained at the temperature which is higher than the boiling point of the processing liquid at the atmospheric pressure. Therefore, the temperature of the liquid film is higher than the boiling point at the atmospheric pressure, in a state where the pressure of the internal space reaches the second pressure by depressurization. Therefore, the processing liquid is instantaneously evaporated, so that the liquid film is instantaneously excluded from the substrate.

As a result, in a configuration in which the vapor layer is formed between the liquid film of the processing liquid and the upper surface of the substrate, the liquid film is excellently excluded from the substrate.

In one preferred embodiment of the present invention, the second pressure is equal to or lower than the atmospheric pressure. Therefore, compared to a configuration in which the second pressure is higher than the atmospheric pressure, the difference between the first pressure and the second pressure can be increased. In other words, compared to the configuration in which the second pressure is higher than the atmospheric pressure, the difference between the temperature of the liquid film and the boiling point of the processing liquid after depressurizing the internal space can be increased. Therefore, in the liquid film excluding step, the evaporation rate when the processing liquid is evaporated is increased. Accordingly, the processing liquid is more instantaneously evaporated, so that the liquid film is more instantaneously excluded from the substrate.

In one preferred embodiment of the present invention, the second pressure is equal to the atmospheric pressure. And, the liquid film excluding step includes a gas discharging step of discharging the gas in the internal space to the outside of the internal space by opening the internal space to the outside of the internal space, in order to reduce the pressure of the internal space.

According to this method, the second pressure is equal to the atmospheric pressure. Therefore, by a simple method of opening the internal space to the outside of the internal space, it is possible to discharge the gas in the internal space to the outside of the internal space and to reduce the internal space. Therefore, in the liquid film excluding step, by reducing the pressure of the internal space with the simple method, the processing liquid can instantaneously be evaporated.

In one preferred embodiment of the present invention, the pressurizing step and the heating step is performed in parallel. Therefore, the time, during which from when the substrate is held by the substrate holding unit to when the depressurization of the internal space of the chamber is started, can be shortened. Therefore, the time required for substrate processing can be shortened.

In one preferred embodiment of the present invention, the liquid film forming step and the pressurizing step is performed in parallel. Therefore, the time, during which from when the substrate is held by the substrate holding unit to when the depressurization of the internal space of the chamber is started, can be shortened. Therefore, the time required for substrate processing can be shortened.

In one preferred embodiment of the present invention, the heating step includes a contact heating step of heating the substrate in a state where a heater unit is in contact with a lower surface of the substrate.

According to this method, the substrate is heated in a state where the heater unit is in contact with the lower surface of the substrate. The substrate is heated efficiently, so that the time required for the heating step can thereby be shortened. Therefore, the time, during which from when the substrate is held by the substrate holding unit to when the depressurization of the internal space of the chamber is started, can be shortened. Therefore, the time required for substrate processing can be shortened.

The another preferred embodiment of the present invention provides a substrate processing apparatus includes a substrate holding unit that holds a substrate horizontally, a chamber that has an internal space which houses the substrate holding unit, a processing liquid supplying unit that supplies a processing liquid, which processes an upper surface of the substrate, to the upper surface of the substrate which is held horizontally, a heater unit that heats the substrate, a gas supplying unit that supplies a gas to the internal space, a reducing pressure unit that reduces a pressure of the internal space, and a controller that controls the substrate holding unit, the chamber, the processing liquid supplying unit, the heater unit, the gas supplying unit and the reducing pressure unit.

And, the controller is programed to perform a substrate holding step that the substrate is held by the substrate holding unit, a sealing step of sealing the internal space in a state of housing the substrate holding unit, a liquid film forming step of forming the liquid film of the processing liquid on the substrate by supplying the processing liquid to the upper surface of the substrate, a pressurizing step of pressurizing the internal space until the pressure of the internal space reaches a first pressure which is higher than an atmospheric pressure, by supplying the gas to the internal space, a heating step of heating the substrate such that a vapor layer of the processing liquid is famed between the liquid film and the substrate in a state where the pressure of the internal space reaches the first pressure, and a liquid film excluding step of excluding the liquid film from the substrate by evaporating the processing liquid, by reducing the pressure of the internal space until the pressure of the internal space reaches a second pressure, which is lower than the first pressure, while keeping a state where the vapor layer of the processing liquid between the liquid film and the substrate is formed.

According to this configuration, in the heating step, the substrate is heated so as to reach high temperature at which the vapor layer is formed between the liquid film and the substrate. Therefore, the vapor layer is famed between the liquid film and the substrate by evaporating the processing liquid near the upper surface of the substrate. Therefore, compared to the configuration in which the processing liquid of the liquid film is gradually evaporated from above, the time during which the surface tension acts on the upper surface of the substrate is shortened.

In the depressurization of the internal space of the liquid film excluding step, the pressure of the internal space is brought to the second pressure which is lower than the first pressure in a state where the vapor layer is maintained. Incidentally, the aforementioned high temperature, at which the vapor layer is formed, is a temperature which is higher than a boiling point at the second pressure. Therefore, the temperature of the liquid film is higher than the boiling point in a state where the pressure of the internal space reaches the second pressure by depressurization. Therefore, the processing liquid is instantaneously evaporated, so that the liquid film is instantaneously excluded from the substrate.

As a result, in a configuration in which the vapor layer is formed between the liquid film of the processing liquid and the upper surface of the substrate, the liquid film is excellently excluded from the substrate.

The another preferred embodiment of the present invention further provides a substrate processing apparatus includes a substrate holding unit that holds a substrate horizontally, a chamber that has an internal space which houses the substrate holding unit, a processing liquid supplying unit that supplies a processing liquid, which processes an upper surface of the substrate, to the upper surface of the substrate which is held horizontally, a heater unit that heats the substrate, a gas supplying unit that supplies a gas to the internal space, a reducing pressure unit that reduces a pressure of the internal space, and a controller that controls the substrate holding unit, the chamber, the processing liquid supplying unit, the heater unit, the gas supplying unit and the reducing pressure unit.

And, the controller is programed to perform a substrate holding step that the substrate is held by the substrate holding unit, a sealing step of sealing the internal space in a state of housing the substrate holding unit, a liquid film forming step of forming the liquid film of the processing liquid on the substrate by supplying the processing liquid to the upper surface of the substrate, a pressurizing step of pressurizing the internal space until the pressure of the internal space reaches a first pressure which is higher than an atmospheric pressure, by supplying the gas to the internal space, a heating step of heating the substrate such that the temperature of the liquid film reaches a temperature which is higher than a boiling point of the processing liquid at the atmospheric pressure in a state where the pressure of the internal space reaches the first pressure, and a liquid film excluding step of excluding the liquid film from the substrate by evaporating the processing liquid so as to pass through a state where the vapor layer of the processing liquid between the liquid film and the substrate is formed, by reducing the pressure of the internal space until the pressure of the internal space reaches a second pressure, which is lower than the first pressure, while keeping a state where the temperature of the liquid film reaches the boiling point of the processing liquid at the atmospheric pressure.

According to this configuration, in the liquid excluding step, by reducing the pressure of the sealed internal space of the chamber, the liquid film is excluded from the substrate after passing through the state in which the vapor layer is formed. The temperature of the substrate reaches high temperature at which the vapor layer is formed between the liquid film and the substrate during depressurization process. Therefore, the processing liquid near the upper surface of the substrate is instantaneously evaporated, and the vapor layer is formed between the liquid film and the substrate. Therefore, compared to the configuration in which the processing liquid of the liquid film is gradually evaporated from above, the time during which the surface tension acts on the upper surface of the substrate is shortened.

In the depressurization of the internal space in the liquid film excluding step, the pressure of the internal space is brought to the second pressure which is lower than the first pressure in a state where the temperature of the liquid film is maintained at the temperature which is higher than the boiling point of the processing liquid at the atmospheric pressure. Therefore, the temperature of the liquid film is higher than the boiling point at the atmospheric pressure, in a state where the pressure of the internal space reaches the second pressure by depressurization. Therefore, the processing liquid is instantaneously evaporated, so that the liquid film is instantaneously excluded from the substrate.

As a result, in a configuration in which the vapor layer is formed between the liquid film of the processing liquid and the upper surface of the substrate, the liquid film is excellently excluded from the substrate.

In another preferred embodiment of the present invention, the second pressure is equal to or lower than the atmospheric pressure. Therefore, compared to a configuration in which the second pressure is higher than the atmospheric pressure, the difference between the first pressure and the second pressure can be increased. In other words, compared to the configuration in which the second pressure is higher than the atmospheric pressure, the difference between the temperature of the liquid film and the boiling point of the processing liquid after depressurizing the internal space can be increased. Therefore, in the liquid film excluding step, the evaporation rate when the processing liquid is evaporated is increased. Accordingly, the processing liquid is more instantaneously evaporated, so that the liquid film is more instantaneously excluded from the substrate.

In another preferred embodiment of the present invention, the second pressure is equal to the atmospheric pressure. And, the reducing pressure unit includes an discharging unit that discharges the gas in the internal space to the outside of the internal space by opening the internal space to the outside of the internal space. And, the controller is programed to perform a gas discharging step of discharging the gas in the internal space to the outside of the internal space in order to reduce the pressure of the internal space by controlling the discharging unit.

According to this configuration, the second pressure is equal to the atmospheric pressure. Therefore, by simple method of opening the internal space to the outside of the internal space, it is possible to discharge the gas in the internal space to the outside of the internal space to reduce the internal space. Therefore, in the liquid film excluding step, by reducing the pressure of the internal space with the simple method, the processing liquid can instantaneously be evaporated.

In another preferred embodiment of the present invention, the controller is programed to perform the pressurizing step and the heating step in parallel. Therefore, the time, during which from when the substrate is held by the substrate holding unit to when the depressurization of the internal space of the chamber is started, can be shortened. Therefore, the time required for substrate processing can be shortened.

In another preferred embodiment of the present invention, the controller is programed to perform the liquid film forming step and the pressurizing step in parallel. Therefore, the time, during which from when the substrate is held by the substrate holding unit to when the depressurization of the internal space of the chamber is started, can be shortened. Therefore, the time required for substrate processing can be shortened.

In another preferred embodiment of the present invention, the substrate processing apparatus further includes a heater elevating/lowering unit that elevates and lowers the heater. And, the controller is programed to perform a contact heating step of heating the substrate in a state where the heater unit is in contact with a lower surface of the substrate by controlling the heater elevating/lowering unit.

According to this configuration, the substrate is heated in a state where the heater unit is in contact with the lower surface of the substrate. The substrate is heated efficiently, so that the time required for the heating step can thereby be shortened. Therefore, the time, during which from when the substrate is held by the substrate holding unit to when the depressurization of the internal space of the chamber is started, can be shortened. Therefore, the time required for substrate processing can be shortened.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an illustrative plan view for explaining a layout of the interior of a substrate processing apparatus according to a first preferred embodiment of the present invention.

FIG. 2 is a schematic cross-sectional view for explaining an example of a structure of a front surface of a substrate to be processed by the substrate processing apparatus.

FIG. 3 is an illustrative partial cross-sectional view to explain a configuration example of a processing unit included in the substrate processing apparatus.

FIG. 4 is a block diagram to explain an electric configuration of a main part of the substrate processing apparatus.

FIG. 5 is a flowchart to describe an example of substrate processing performed by the substrate processing apparatus.

FIG. 6 is a flowchart to explain a drying process (S4 of FIG. 5).

FIG. 7A to FIG. 7F are illustrative sectional view for explaining the drying process (S4 of FIG. 5).

FIG. 8A to FIG. 8C are schematic cross-sectional view of around an upper surface of the substrate when a liquid film is excluded from the substrate in a case where a vapor layer is formed in a heating step.

FIG. 9A to FIG. 9C are schematic cross-sectional view of around an upper surface of the substrate when a liquid film is excluded from the substrate in a case where a vapor layer is formed in a liquid film excluding step.

FIG. 10 is an illustrative partial cross-sectional view to explain a configuration example of a processing unit which is included in the substrate processing apparatus according to a second preferred embodiment of the present invention.

FIG. 11 is an illustrative cross-sectional view to explain the principle of a pattern collapse caused by surface tension.

### DETAILED DESCRIPTION OF THE PREFERRED EMBODIMENTS

### First Preferred Embodiment

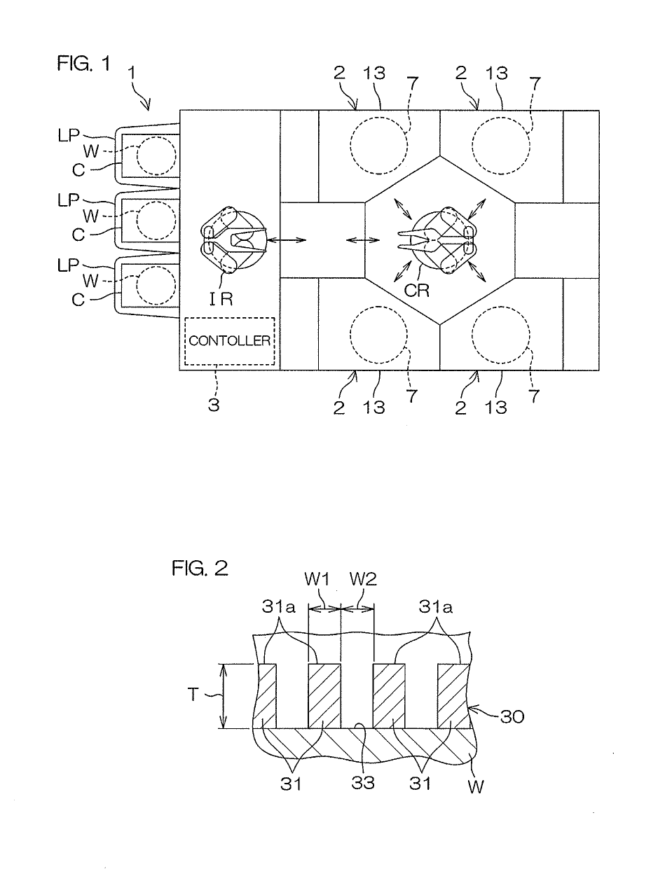

FIG. 1 is an illustrative plan view for explaining a layout of the interior of a substrate processing apparatus 1 according to a first preferred embodiment of the present invention.

The substrate processing apparatus 1 is a single substrate processing type apparatus that processes a substrate W, such as a silicon wafer, one by one. In the present preferred embodiment, the substrate W is a circular substrate. The substrate processing apparatus 1 includes a plurality of processing units 2 each of which processes the substrate W by use of a processing liquid, a plurality of load ports LP each of which holds a carrier C that houses a plurality of the substrates W to be processed by the processing units 2, transfer robots IR and CR that transfer the substrates W between the load ports LP and the processing units 2, and a controller 3 that controls the substrate processing apparatus 1. The transfer robot IR transfers the substrate W between the carriers C and the transfer robot CR. The transfer robot CR transfers the substrate W between the transfer robot IR and the processing units 2. The plurality of processing units 2 have, for example, the same configuration. The processing liquid is a liquid for processing an upper surface of the substrate W. A rinse liquid such as deionized water (DIW) and a low surface tension liquid such as IPA having a surface tension lower than that of water are included in the processing liquid.

FIG. 2 is a schematic cross-sectional view for explaining an example of a structure of the upper surface 33 of the substrate W to be processed by the substrate processing apparatus 1. Referring to FIG. 2, the substrate W which is processed by the substrate processing apparatus 1 is, for example, a silicon wafer with a front surface on which a fine pattern 30 is formed. The fine pattern 30 has a plurality of convex structures 31. The plurality of convex structures 31 are arranged along the same direction as each other.

a pattern width W1 of each structure 31 is usually about 10 nm to 45 nm. A gap W2 of the fine pattern 30 is about 10 nm to several μm. The fine pattern 30 may be a pattern of line shaped structure. In this case, a groove shaped (trench shaped) gas is provided in the fine pattern 30.

The fine pattern 30 usually includes insulating film. The fine pattern 30 may include conductive film. More specifically, the fine pattern 30 may be formed of a laminated film in which an insulating film and a conductive film are laminated. The fine pattern 30 may be composed of a single layer film.

The insulating film may be SiO₂ film or nitride film. Further, the conductive film may be an amorphous silicon film into which an impurity for lowering the resistance is introduced, or may be a metal film (for example, a metal wiring film).

Polysilicon film, SIN film, BSG film (SiO₂ film containing boron), TEOS film (SiO₂ film formed by CVD method using TEOS (tetraethoxysilane)) and the like can be exemplified as each film constituting the laminated film.

Further, a film thickness T of the fine pattern 30 is, for example, about 50 nm to 5 μm. In the fine pattern 30, the aspect ratio may be, for example about 5 to 500 (typically about 5 to 50). The aspect ratio is ratio of the film thickness T to the pattern width W1.

When drying the substrate Won which such the fine pattern 30 is formed, surface tension (see FIG. 11), that attracts adjacent structures 31 to each other, acts on the fine pattern 30. As a result, the fine pattern 30 may cause pattern collapse.

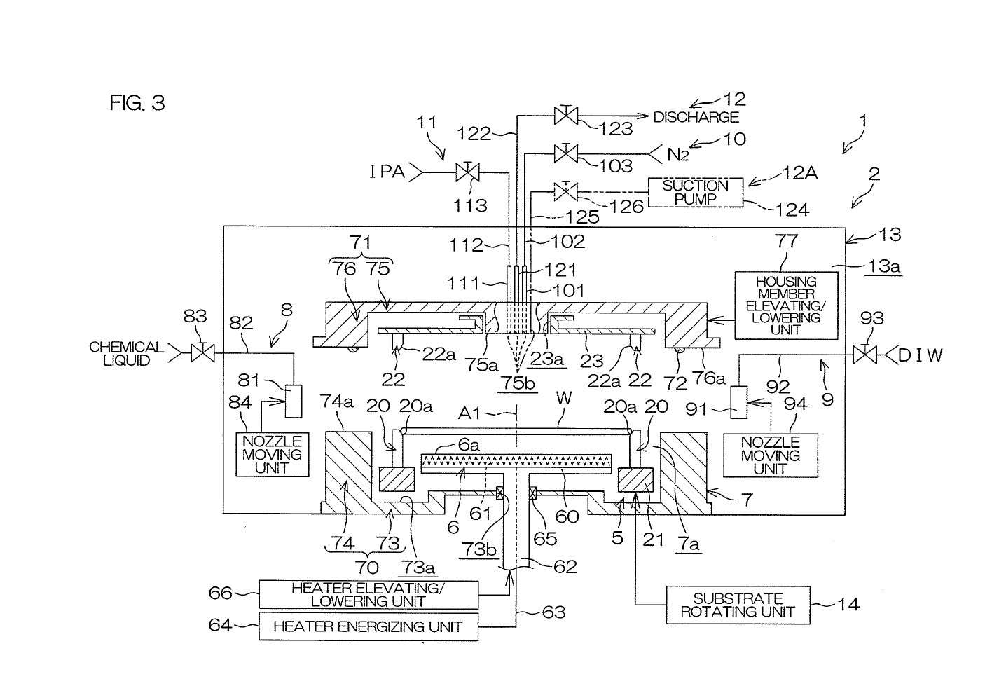

FIG. 3 is an illustrative partial cross-sectional view to explain a configuration example of the processing unit 2.

The processing unit 2 includes a substrate holding unit 5 which holds one substrate W in a horizontal attitude, a heater unit 6 which heats the substrate W, a sealed chamber 7 which has a sealable internal space 7a, a chemical liquid supplying unit 8 which supplies a chemical liquid to the upper surface of the substrate W and a rinse supplying unit 9 which supplies the rinse liquid such as DIW to the upper surface of the substrate W.

The processing unit 2 includes a gas supplying unit 10 which supplies a gas such as nitrogen gas (N₂) to the internal space 7a, a low surface tension liquid supplying unit 11 which supplies a low surface tension liquid such as IPA to the upper surface of the substrate W, an discharging unit 12 which discharges the gas in the internal space 7a to the outside of the sealed chamber 7, and a housing chamber 13 which houses the sealed chamber 7.

A carry-in/carry-out port (not shown) that carries in/out the substrate W is formed in the housing chamber 13. The housing chamber 13 is provided with a shutter unit (not shown) that opens and closes the carry-in/carry-out port.

The substrate holding unit 5 includes a plurality of lower side contact pins 20 which can be in contact with the substrate W from the lower side, a lower side supporting member 21 which supports the plurality of lower side contact pins 20 from the lower side, a plurality of upper side contact pins 22 which can be in contact with the substrate W from the upper side and a upper side supporting member 23 which supports the plurality of upper side contact pins 22 from the upper side. Each of the lower side supporting member 21 and the upper side supporting member 23 is an annular shaped in this embodiment.

The processing unit 2 includes a substrate rotating unit 14 which rotates the substrate W around the rotational axis A1. The substrate rotating unit 14 includes an electric motor (not shown) which gives a rotational force to the lower side supporting member 21. By being rotated the lower side supporting member 21 by the electric motor, the substrate W, which is held by the substrate holding unit 5, is rotated around the rotational axis A1.

The plurality of lower side contact pins 20 are disposed at intervals in a circumferential direction at an upper surface of the lower side supporting member 21. The lower side contact pin 20 has an inclined surface 20a which is inclined with respect to a horizontal direction. The lower side contact pin 20 is disposed such that the inclined surface 20a faces the rotational axis A1 side.

The plurality of upper side contact pins 22 are disposed at intervals in the circumferential direction on a peripheral portion of an lower surface of the upper side supporting member 23. The upper side contact pin 22 has an inclined surface 22a which is inclined with respect to the horizontal direction. The upper side contact pin 22 is disposed such that the inclined surface 22a faces the rotational axis A1 side.

The substrate W is horizontally placed on the plurality of the lower side contact pins 20. When the substrate W is placed on the plurality of the lower side contact pins 20, the inclined surface 20a of the lower side contact pin 20 is contact with a peripheral side of the lower surface of the substrate W. Thus, the substrate W is horizontally held by the substrate holding unit 5. The substrate W is securely held horizontally by being gripped by the plurality of the lower side contact pins 20 and the plurality of the upper side contact pins 22.

Unlike this embodiment, the substrate holding unit 5 may be a grip type chuck which hold the substrate W horizontally by gripping the substrate from the horizontal direction.

The sealed chamber 7 is an example of a chamber which has the internal space 7a which can house the substrate holding unit 5. The sealed chamber 7 has a lower side housing member 70 which has an opening at its upper end, an upper side housing member 71 which is disposed above the lower side housing member 70 and has an opening at its lower end. Each of the lower side housing member 70 and the upper side housing member 71 has a cylindrical form having a bottom. The lower side supporting member 21 is housed in the lower side housing member 70. The upper side supporting member 23 is housed in the upper side housing member 71.

The lower side housing member 70 integrally has a bottom wall 73 which is substantially disk shaped and a peripheral wall 74 which extends upward from the bottom wall 73. The peripheral wall 74 has a cylindrical shape that is centered on the rotational axis A1. The peripheral wall 74 has an upper end surface 74a which is annular ring shaped.

An annular groove 73a, to which a waste liquid pipe (not shown) or a recovery pipe (not shown) is connected, is formed on an upper surface of the bottom wall 73. The chemical liquid and rinse liquid which are led to the annular groove 73a are wasted or recovered through the waste liquid pipe or the recovery pipe.

The upper side housing member 71 integrally has a bottom wall 75 which is substantially disk shaped and a peripheral wall 76 which extends downward from the bottom wall 75. The peripheral wall 76 has a cylindrical shape that is centered on the rotational axis A1. The peripheral wall 76 has a lower end surface 76a which is annular ring shaped.

A sealing member 72 which is annular ring shaped is provided between a peripheral portion of the upper side housing member 71 and a peripheral portion of the lower side housing member 70. For details, the sealing member 72 is provided between the upper end surface 74a of the peripheral wall 74 of the lower side housing member 70 and the lower end surface 76a of the peripheral wall 76 of the upper side housing member 71. In this embodiment, the sealing member 72 is attached to the lower end surface 76a of the peripheral wall 76 of the upper side housing member 71.

A cylindrical central projection 75a, which is provided at a central region of the bottom wall 75 of the upper side housing member 71, is inserted through an insertion hole 23a which is provided at a central region of the upper side supporting member 23. Thus, the upper side supporting member 23 is held by the upper side housing member 71 so as to be rotatable around the rotational axis A1 with respect to the upper side housing member 71.

A housing member elevating/lowering unit 77 which elevates and lowers the upper side housing member 71 is bound to the upper side housing member 71. The housing member elevating/lowering unit 77 has, for example, a ball screw mechanism (not shown) and an electric motor (not shown) that gives it a driving force. The upper side supporting member 23 is supported by the upper side housing member 71, so that the upper side supporting member 23 can integrally elevate and lower with the upper side housing member 71.

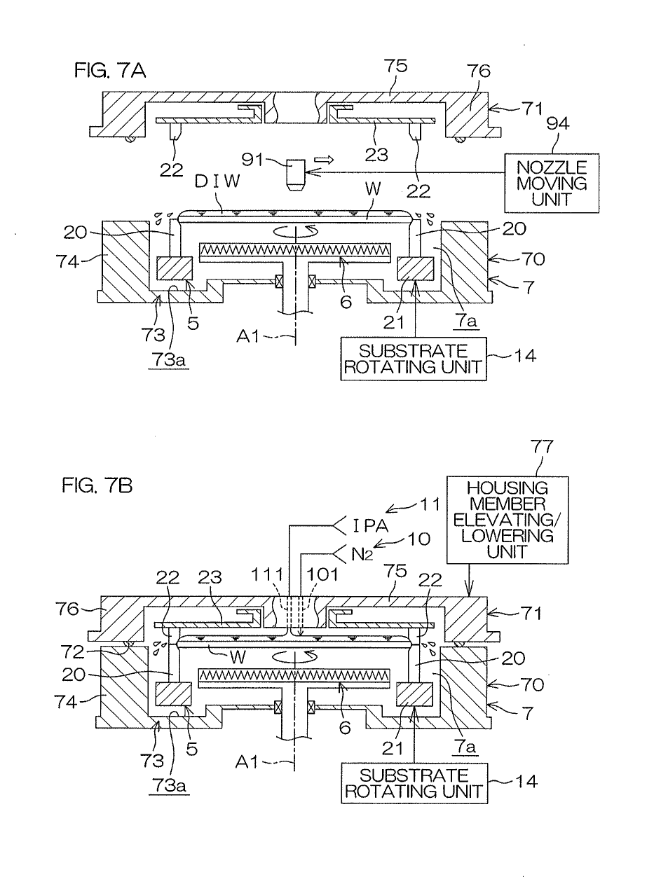

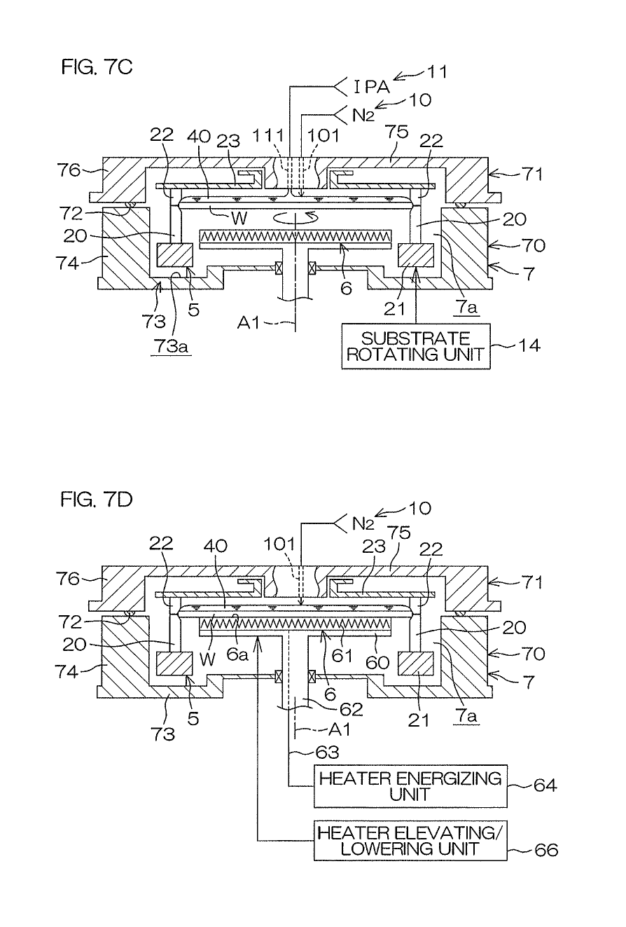

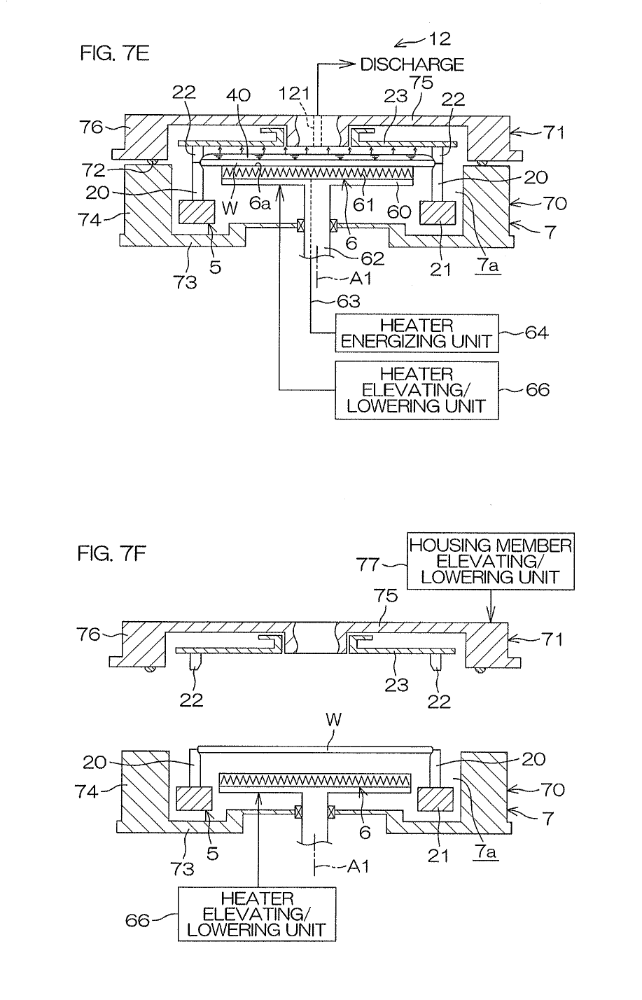

The upper side housing member 71 can elevate and lower between a lower position and an upper position. The lower position of the upper side housing member 71 is a position (the position shown in FIG. 7B to be described later) of the upper side housing member 71 when the sealing member 72 is compressed between the upper side housing member 71 and the lower side housing member 70. The upper position of the upper side housing member 71 is a position (the position shown in FIG. 7A to be described later) at which the upper side housing member 71 separates from the lower side housing member 70. When the upper side housing member 71 positions at the lower position, a space between the upper side housing member 71 and the lower side housing member 70 is sealed by the sealing member 72, so that the internal space 7a of sealed chamber 7 is sealed. In a state where the internal space 7a is sealed, the substrate holding unit 5 is housed in the internal space 7a.

When the upper side housing member 71 positions at the lower position, the plurality of the upper side contact pins 22 are in contact with the substrate W from the upper side. Therefore, the substrate W is gripped by the plurality of the lower side contact pins 20 and the plurality of the upper side contact pin 22. When the lower side supporting member 21 is rotated by the substrate rotating unit 14 while the substrate W is gripped by the plurality of the lower side contact pins 20 and the plurality of the upper side contact pins 22, the lower side supporting member 21, the upper side supporting member 23 and the substrate W integrally rotate around the rotational axis A1. That is, the substrate W, which is held by the substrate holding unit 5, is rotated around the rotational axis A1 by the substrate rotating unit 14.

The heater unit 6 disposed below the substrate W. The heater unit 6 has the foam of a disk shaped hot plate. The heater unit 6 has a facing surface 6a which faces the lower surface of the substrate W from below.

The heater unit 6 includes a plate body 60 and a heater 61. The plate body 60 is configured in a circular shape around the rotational axis A1. More precisely, the plate body 60 has a circular plane shape of which a diameter is slightly smaller than a diameter of the substrate W.

The heater 61 may be a resistor which is built in the plate body 60. The facing surface 6a is heated to a higher temperature than room temperature (For example, 20° C. to 30° C. For example, 25° C.) by energizing the heater 61. Specifically, by energizing the heater 61, the facing surface 6a can be heated to a temperature higher than a boiling point (86.4° C.) of the IPA at an atmospheric pressure.

An elevating/lowering shaft 62 which extends in a vertical direction along the rotational axis A1 is connected to a lower surface of the heater unit 6. A power supplying line 63 which is connected to the heater 61 is inserted through the elevating/lowering shaft 62. And, a heater energizing unit 64 which supplies an electric power to the heater 61 is connected to the power supplying line 63.

The elevating/lowering shaft 62 is inserted through a through hole 73b which is formed a central part of the bottom wall 73 of the lower side housing member 70. A lower end of the elevating/lowering shaft 62 extends further downward than the bottom wall 73. A space between the elevating/lowering shaft 62 and the through hole 73b is sealed by a sealing member 65 which is annular ring shaped. Therefore, although the through hole 73b is provided in the lower side housing member 70, the sealability of the internal space 7a can be ensured sufficiently.

The processing unit 2 has a heater elevating/lowering unit 66 which elevates and lowers the heater unit 6. The heater elevating/lowering unit 66 is connected to the elevating/lowering shaft 62. By operating the heater elevating/lowering unit 66, the heater unit 6 moves up and down between a lower position (the position shown in FIG. 7A to be described later) at which the heater unit 6 is separated from the lower surface of the substrate W and an upper position (a contact position, the position shown in FIG. 7D to be described later) which is a position of the heater unit 6 when the facing surface 6a is in contact with the substrate W.

In a state where the heater unit 6 is not in contact with the substrate W, the substrate W can be heated by a radiant heat from the facing surface 6a. When the heater unit 6 positioned at the contact position, the substrate W is heated with a large amount of heat by heat conduction from the facing surface 6a.

The heater elevating/lowering unit 66 includes, for example, a ball screw mechanism (not shown), and an electric motor (not shown) which gives a driving force to the ball screw mechanism.

the chemical liquid supplying unit 8 includes a chemical liquid nozzle 81 which supplies the chemical liquid to the upper surface of the substrate W, a chemical liquid supply pipe 82 which is connected to the chemical liquid nozzle 81, and a chemical liquid valve 83 which is interposed in the chemical liquid supply pipe 82 and opens and closes the flow path of the chemical liquid. The chemical liquid such as hydrofluoric acid is supplied to the chemical liquid supply pipe 82 from a chemical liquid supply source.

The chemical liquid is not limited to hydrofluoric acid but may be a liquid containing at least one of sulfuric acid, acetic acid, nitric acid, hydrochloric acid, hydrofluoric acid, aqueous ammonia, aqueous hydrogen peroxide, organic acid (For example, citric acid, oxalic acid etc.), organic alkali (For example TMAH: tetramethylammonium hydroperoxide, etc.), a surfactant, and a corrosion inhibitor. Examples of the chemical liquid obtained mixing them includes SPM (sulfuric acid/hydrogen peroxide mixture), SC1 (ammonia-hydrogen peroxide mixture) and the like.

the chemical liquid nozzle 81 is moved in the vertical direction and the horizontal direction by a chemical liquid nozzle moving unit 84. By moving in the horizontal direction, the chemical liquid nozzle 81 can move between a center position at which the chemical liquid nozzle 81 faces a rotation center position of the upper surface of the substrate W and a retract position at which the chemical liquid nozzle 81 does not face the upper surface of the substrate W. The rotation center position of the upper surface of the substrate W is a position of intersection with the rotational axis A1 on the upper surface of the substrate W. The retract position not face the upper surface of the substrate W, is a position outside the sealed chamber 7 in plan view. Unlike this embodiment, the chemical liquid nozzle 81 may be a fixed nozzle which is disposed outside the sealed chamber 7.

The rise liquid supplying unit 9 includes a rinse liquid nozzle 91, which supplies the rinse liquid to the upper surface of the substrate W, a rinse liquid supply pipe 92 which is connected to the rinse liquid nozzle 91, and a rinse liquid valve 93 which is interposed in the rinse liquid supply pipe 92 and opens and closes a flow path of the rinse liquid. The rinse liquid such as DIW is supplied to the rinse liquid supply pipe 92 from a rinse liquid supply source.

The rinse liquid is not limited to DIW, but may be carbonated water, electrolytic ionized water, ozone water, hydrochloric acid water of dilution concentration (for example, about 10 ppm to 100 ppm), aqueous ammonia, reduced water (hydrogen water).

The rinse liquid nozzle 91 is moved in the vertical direction and the horizontal direction by a rinse liquid nozzle moving unit 94. By moving in the horizontal direction, the rinse liquid nozzle 91 can move between a center position at which the rinse liquid nozzle 91 faces a rotation center position of the upper surface of the substrate W and a retract position at which the rinse liquid nozzle 91 does not face the upper surface of the substrate W. Unlike this embodiment, the rinse liquid nozzle 91 may be a fixed nozzle which is disposed outside the sealed chamber 7.

the gas supplying unit 10 includes a gas nozzle 101 which supplies the gas such as nitrogen gas to a center region of the upper surface of the substrate W, a gas supply pipe 102 which is connected to the gas nozzle 101, and a gas valve 103 which is interposed in the gas supply pipe 102 and opens and closes a flow path of the gas. The gas such as nitrogen gas is supplied to the gas supply pipe 102 from a gas supply source.

As the gas which is supplied from the gas supply source to the gas supply pipe 102, an inert gas such as nitrogen gas is preferable. The inert gas is not limited to nitrogen gas but may be any gas which is inert to the upper surface of the substrate W and the fine pattern 30 (see FIG. 2). As an example of the inert gas, besides nitrogen gas, rare gases such as argon can be mentioned.

The low surface tension liquid supplying unit 11 is one example of a processing liquid supplying unit which supplies the processing liquid, which processes the upper surface of the substrate W, to the upper surface of the substrate W. The low surface tension liquid supplying unit 11 includes a low surface tension liquid nozzle 111 which supplies the low surface tension liquid such as IPA to the center region of the upper surface of the substrate W, a low surface tension liquid supply pipe 112 which is connected to the low surface tension liquid nozzle 111, and a low surface tension liquid valve 113 which is interposed in the low surface tension liquid supply pipe 112 and opens and closes a flow path of the low surface tension liquid. The low surface tension liquid such as IPA is supplied to the low surface tension supply pipe 112 from a low surface tension supply source.

As the low surface tension liquid which is supplied from the low surface tension liquid supply source to the low surface tension liquid supply pipe 112, an organic solvent other than IPA, which does not chemically react (has poor reactivity) with the upper surface of the substrate W and the fine pattern 30 (see FIG. 2), can be used. More specifically, a liquid containing at least one of IPA, HFE (hydrofluoroether), methanol, ethanol, acetone and Trans-1,2-dichloroethylene can be used as the low surface tension liquid. Additionally, the low surface tension liquid is not necessarily composed of only a single component but may be a liquid mixed with other components. For example, the low surface tension liquid may be a mixed solution of IPA liquid and pure water, or a mixed liquid of IPA liquid and HFE liquid.

The discharging unit 12 includes a discharge pipe 122 which leads the gas in the internal space 7a to the outside of the sealed chamber 7, and the discharge valve 123 which opens and closes the discharge pipe 122. By opening the discharge valve 123 in a state where the internal space 7a is sealed, the gas moves between the internal space 7a and the outside of the internal space 7a. Thus, a pressure in the internal space 7a and a pressure outside of the internal space 7a become uniform.

A tip portion 121 of the discharge pipe 122, the gas nozzle 101 and the low surface tension liquid nozzle 111 are inserted through a plurality of insertion holes 75b which is provided in the central projection 75a of the bottom wall 75 of the upper side housing member 71, respectively. The gap between each of the tip portion 121 of the discharge pipe 122, the gas nozzle 101 and the low surface tension liquid nozzle 111, and the upper side housing member 71 is sealed with a seal member (not shown) or the like. Therefore, although the plurality of the insertion holes 75b are provided in the upper side housing member 71, the sealability of the internal space 7a can be ensured sufficiently.

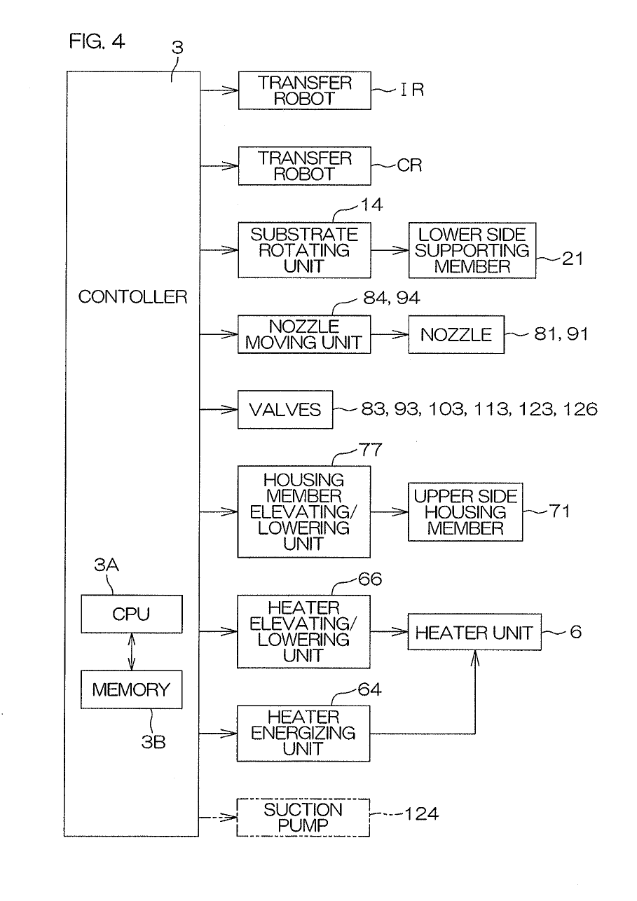

FIG. 4 is a block diagram to explain an electric configuration of a main part of the substrate processing apparatus 1. The controller 3 includes a microcomputer, and controls the control objects included in the substrate processing apparatus 1 in accordance with a predetermined control program. More specifically, the controller 3 includes a processor (CPU) 3A and a memory 3B in which a control program is stored, and is configured to perform various controls for substrate processing by executing the control program by the processor 3A. Particularly, the controller 3 controls operations of the transfer robots IR and CR, the substrate rotating unit 14. the nozzle moving unit 84 and 94, the valves 83, 93, 103, 113 and 123, the housing member elevating/lowering unit 77, the heater elevating/lowering unit 66, the heater energizing unit 64 , etc.

FIG. 5 is a flowchart to describe an example of substrate processing performed by the substrate processing apparatus 1. In the substrate processing by the substrate processing apparatus 1, for example, as shown in FIG. 5, a carry-in of substrate (S1), a chemical liquid process (S2), a rinse process (S3), a drying process (S4) and a carry-out of substrate (S5) are executed in this order based on the processing schedule created by the controller 3.

First, in the substrate processing, the carry-in of substrate (S1) is performed. During the carry-in of substrate (S1), the heater unit 6 positions at the lower position and the upper side housing member 71 positions at the upper position. An unprocessed substrate W is carried from the carrier C into the processing unit 2 by the transfer robots IR and CR, and is placed on the lower side contact pin 20 (S1). Thereafter, the substrate W is horizontally held by the substrate holding unit 5 until the substrate W is carried out by the transfer robot CR (a substrate holding step).

Next, the chemical liquid process (S2) is started after the transfer robot CR retreats to the outside of the processing unit 2.

The substrate rotating unit 14 rotates the lower side supporting member 21. As a result, the substrate W which is held horizontally rotates (a substrate rotating step). On the other hand, the chemical liquid nozzle moving unit 84 places the chemical liquid nozzle 81 at a chemical liquid processing position that is above the substrate W. The chemical liquid processing position may be a position where the chemical liquid discharged from the chemical liquid nozzle 81 lands at the rotational center of the upper surface of the substrate W. Then, the chemical liquid valve 83 is opened. As a result, the chemical liquid is suppled from the chemical liquid nozzle 81 toward the upper surface of the rotating substrate W. The chemical solution supplied thereto spreads across the entirety of the upper surface of the substrate W by means of a centrifugal force.

In the substrate processing, the chemical liquid which is supplied on the rotational substrate W scatters outward from the periphery of the substrate W by centrifugal force and is received by the peripheral wall 74 of the lower side housing member 70. Then, the chemical liquid which is received by the peripheral wall 74 is led to the annular groove 73a, which is provided in the bottom wall 73, and is wasted or recovered through the waste liquid pipe or the recovery pipe. The rinse liquid and the low surface tension liquid which will be described later is also recovered or wasted by the same route as the chemical liquid.

Next, the DIW rinse process (S3) for removing the chemical liquid from the substrate W is executed by replacing the chemical liquid on the substrate W with DIW after the chemical liquid processing for a fixed time.

The rinse liquid nozzle moving unit 94 places the rinse liquid nozzle 91 at a rinse liquid processing position that is above the substrate W. The rinse liquid processing position may be a position where the chemical liquid discharged from the rinse liquid nozzle 91 lands at the rotational center of the upper surface of the substrate W. Then, the chemical liquid valve 83 is closed and the rinse liquid valve 93 is opened. As a result, the DIW is suppled from the rinse liquid nozzle 91 toward the upper surface of the rotating substrate W. The DIW supplied thereto spreads across the entirety of the upper surface of the substrate W by means of a centrifugal force. The chemical liquid on the substrate W is washed away by this DIW. Meanwhile, the chemical liquid nozzle moving unit 84 retreats the chemical liquid nozzle 81 from above the substrate W to the side of the sealed chamber 7.

Next, as will be described in detail later, the drying process (S4) for drying the substrate W is executed after the DIW rinse process (S3) for a fixed time. The drying process (S4) is executed in a state where the housing member elevating/lowering unit 77 seals the internal space 7a of the sealed chamber 7 by moving the upper side housing member 71 to the lower position (a sealing step). After the substrate W is dried in the drying process (S4), the housing member elevating/lowering unit 77 moves the upper side housing member 71 to the upper position. Thereafter, the transfer robot CR enters the processing unit 2, and scoops an already-processed substrate W from the substrate holding unit 5, and carries it out of the processing unit 2 (S5). The substrate W is delivered from the transfer robot CR to the transfer robot IR, and is stored in the carrier C by means of the transfer robot IR.

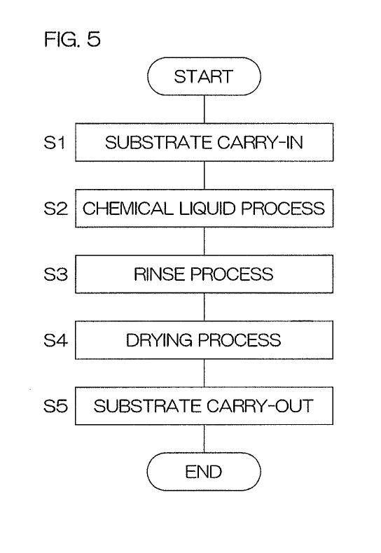

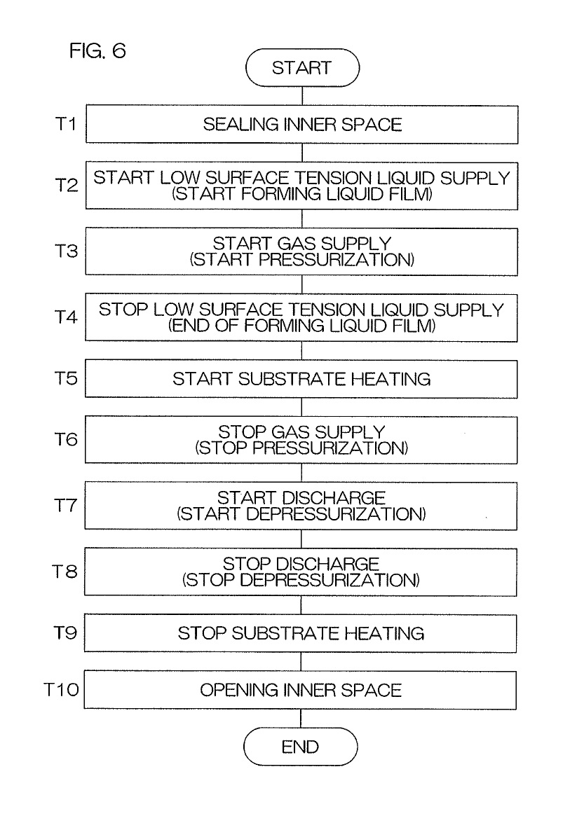

FIG. 6 is a flowchart to explain a drying process (S4 of FIG. 5). FIG. 7A to FIG. 7F are illustrative sectional view for explaining the drying process (S4 of FIG. 5).

As shown in FIG. 7A, in the drying process (S4 of FIG. 5), the rinse liquid valve 93 is closed first. Then, the rinse liquid nozzle moving unit 94 retreats the rinse liquid nozzle 91 from above the substrate W to the side of the sealed chamber 7.

Next, as shown in FIG. 7B, the housing member elevating/lowering unit 77 moves the upper side housing member 71 to the lower position. As a result, the sealing step of sealing the internal space 7a of the sealed chamber 7 is executed (step T1). Then, the low surface tension liquid valve 113 is opened. As a result, supply of the low surface tension liquid such as IPA from low surface tension liquid nozzle 111 to the upper surface of the substrate W is started (step T2). That is, a low surface tension liquid supplying step is started. In this substrate process, the low surface tension liquid supplying step is started after finishing the sealing step. However, the low surface tension liquid supplying step may be started before starting the sealing step or may be started in the middle of the sealing step.

Then, the gas valve 103 is opened. As a result, supply of the gas such as nitrogen gas from the gas nozzle 101 to the internal space 7a of the sealed chamber 7 is started (step T3). On the other hand, the discharge valve 123 is maintained in the closed state. Therefore, the gas supplied to the internal space 7a stays in the internal space 7a without being discharged to the outside of the internal space 7a, so that the internal space 7a is pressurized (a pressurizing step).

Then, as shown in FIG. 7C, after the DIW is replaced by the IPA, a liquid film 40 of the IPA is formed on the substrate W by maintaining supplying of the IPA to the upper surface of the substrate W (a liquid film forming step).

Then, as shown in FIG. 7D, supply of the IPA to the upper surface of the substrate W by closing the low surface tension liquid valve 113 (step T4). As a result, the low surface tension liquid supplying step is finished. The liquid film forming step is started simultaneously with the start of the low surface tension liquid supplying step and finishes simultaneously with the end of the low surface tension liquid supplying step. The pressurizing step is started in the middle of the low surface tension liquid supplying step. In other words, the pressurizing step and the liquid film forming step is executed in parallel.

Then, the substrate rotating unit 14 stops the rotation of the substrate holding unit 5. After stopping the rotation of the substrate W, the heater elevating/lowering unit 66 places the heater unit 6 at the upper position. As a result, the facing surface 6a of the heater unit 6 is in contact with the lower surface of the substrate W. In this state, the heater energizing unit 64 starts energizing the heater unit 6. As a result, the temperature of the heater unit 6 rises and a heating step (a contact heating step) of heating the substrate W is started (step T5). In the heating step, the substrate W is heated to a temperature which is about 10° C. to 100° C. higher than the boiling point (82.6° C.) of the IPA at the atmospheric pressure.

When the liquid film 40 on the substrate W can be sufficiently heated by radiation heat of the heater unit 6, it is not always necessary to bring the plate body 60 into contact with the lower surface of the substrate W. The heater energizing unit 64 may be energized at all times during operation of the substrate processing apparatus 1.

When the pressure of the internal space 7a reaches a first pressure, supply of gas to the internal space 7a is stopped by closing the gas valve 103 (step T6). As a result, the pressurizing step is finished. The first pressure is a pressure which is higher than the atmospheric pressure.

Heating of the substrate W is carried out such that the temperature of the liquid film 40 of the IPA at the time, when the pressure of the internal space 7a reaches the first pressure, becomes a temperature (for example, 90° C. to 100° C.) which is higher than the boiling point (82.6° C.) of the IPA at the atmospheric pressure. A state of the liquid film 40 heated to a temperature higher than the boiling point of the IPA is referred to as an overheated state.

The pressurizing step and the heating step are executed in parallel such that the temperature of the liquid film 40 does not exceed the boiling point of the IPA at the pressure of the internal space 7a.

Then, as shown in FIG. 7E, a reducing pressure step of reducing the pressure in the internal space 7a until the pressure in the internal space 7a reaches a second pressure, which is lower than the first pressure, in a state where the temperature of the liquid film 40 is maintained at a temperature higher than the boiling point of the IPA at the atmospheric pressure, is started. In this embodiment, the discharge valve 123 of the discharging unit 12 is opened in order to reduce the pressure of the internal space 7a. As a result, the internal space 7a is opened to the outside of the internal space 7a (for example, an inner space 13a of the housing chamber 13). Then, the gas in the internal space 7a is discharged outside the internal space 7a through the discharge pipe 122 (a gas discharging step). Depressurization of the internal space 7a takes place in about 1 second. Thus, the discharging unit 12 functions a reducing pressure unit which reduces the pressure in the internal space 7a.

When the pressure of the internal space 7a reaches the second pressure, the discharge valve 123 is closed (step T8). As a result, the gas discharging step (the reducing pressure step) is finished. The pressure outside of the internal space 7a is equal to the atmospheric pressure, so that the pressure (the second pressure) of the internal space 7a after the completion of the reducing pressure step is equal to the atmospheric pressure.

The pressure of the internal space 7a is reduced until the pressure of the internal space 7a reaches the second pressure, whereby the boiling point of the IPA is decreased. Therefore, the temperature of the liquid film 40 becomes higher than the boiling point, so that the IPA vigorously (instantaneously) evaporates as compared with the case where the temperature of the liquid film 40 is the same as the boiling point. Therefore, the liquid film 40 of the IPA is excluded from the substrate W (a liquid film excluding step).

Then, as shown in FIG. 7F, after the liquid film 40 of the IPA is excluded from the substrate W, the heater elevating/lowering unit 66 places the heater unit 6 at the lower position, in order to separate the heater unit 6 from the substrate W. Then, energization by the heater energizing unit 64 to the heater unit 6 is stopped. As a result, the heating step (the contact heating step) of heating the substrate W is finished (step T9).

As the housing member elevating/lowering unit 77 moves the upper side housing member 71, the sealed chamber 7 is opened up and down. As a result, the internal space 7a is opened outside of the sealed chamber 7 (step T10). Thereafter, as described above, the carry-out of substrate (S5 of FIG. 5) is executed.

Incidentally, after finishing the liquid film excluding step and before opening the internal space 7a, a spin drying for spinning the IPA on the substrate W by rotating the substrate W at high speed. Specifically, the substrate rotating unit 14 rotates the substrate W at a predetermined drying speed. The drying speed is, for example, about 500 rpm to 3000 rpm. As a result, a large centrifugal force acts on the IPA on the substrate W, and the IPA on the substrate W is spun off around the substrate W.

During the spin drying, the internal space 7a is sealed, so that the upper side housing member 71 is disposed at the lower position. Therefore, the substrate W is gripped in the vertical direction by the plurality of the lower side contact pins 20 and the plurality of the upper side contact pins 22. Therefore, the substrate W can be rotated stably.

When the liquid film 40 on the substrate W is excluded in the drying process (S4), a vapor layer 41 is formed between the upper surface 33 of the substrate W and the liquid film 40. In this substrate process, there may be a case where the vapor layer 41 is formed in the heating step and a case where the vapor layer 41 is formed in the liquid film excluding step (the reducing pressure step).

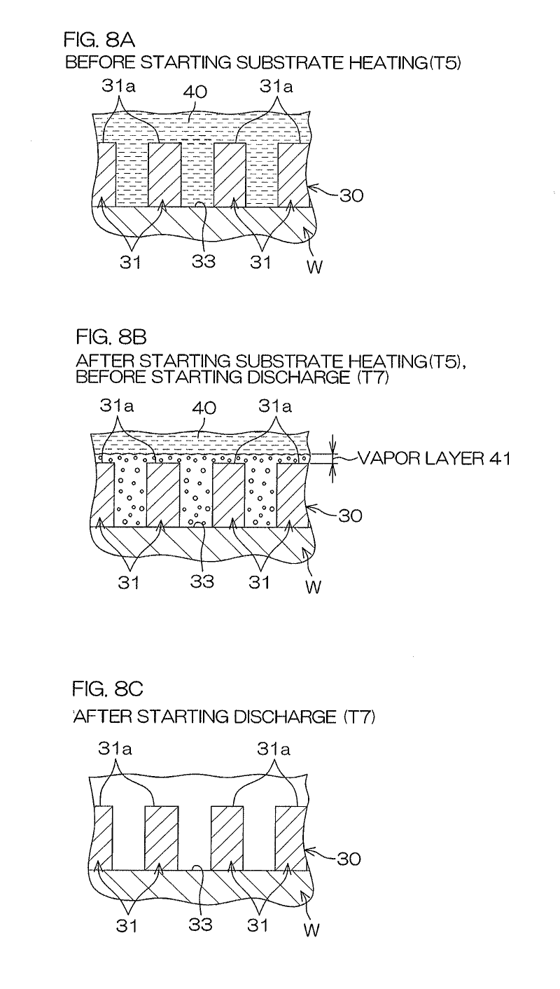

First, a state near the upper surface of the substrate W, in the case where the vapor layer 41 is formed in the heating step, is explained. FIG. 8A to FIG. 8C are schematic cross-sectional view of around an upper surface 33 of the substrate W when the liquid film 40 is excluded from the substrate W in the case where the vapor layer 41 is foamed in the heating step.

As shown in FIG. 8A, in a state where the liquid film 40 of the low surface tension liquid such as the IPA is formed (T4 of FIG. 6), the IPA spreads to the bottom of the gap of the fine pattern 30 which is formed on the upper surface 33 of the substrate W. In the drying process (S4 of FIG. 5), this state is maintained until the heating step is started (before step T5).

Then, in the heating step, the temperature of the liquid film 40 reaches a temperature that is higher than the boiling point of the IPA at the atmospheric pressure (the second pressure) by heating the substrate W, a part of the liquid film 40 of the IPA on the upper surface 33 of the substrate W thereby evaporates and vaporizes. As a result, a vapor of the IPA fills the gap of the fine pattern 30, and the liquid film 40 of the IPA floats from the surface of the substrate W (an upper surface 31a of each structure 31). As a result, as shown in FIG. 8B, the vapor layer 41 is formed between the substrate W and the liquid film 40. The vapor layer 41 is formed after heating of the substrate W is started and the liquid film 40 is sufficiently heated (at least after step T5 of FIG. 6), and before discharging of the internal space 7a is started (at least before step T7 of FIG. 6).

When the internal space 7a is discharged in a state where the vapor layer 41 is formed (after step T7 of FIG. 6), the IPA constituting the liquid film 40 evaporates and the liquid film 40 is excluded from the substrate W as shown in FIG. 8C.

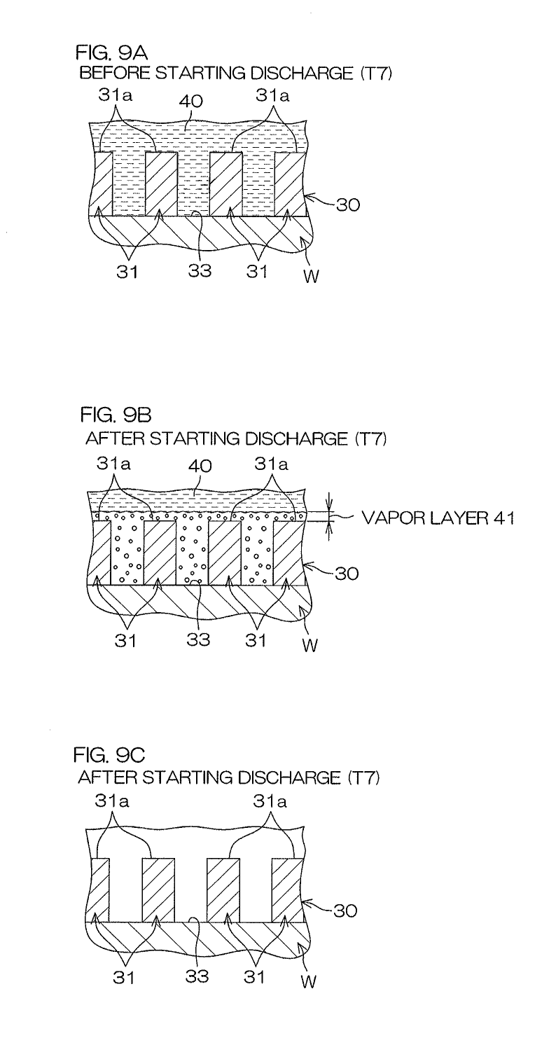

Next, a state near the upper surface of the substrate W, in the case where the vapor layer 41 is formed in the liquid film excluding step (the reducing pressure step), is explained. FIG. 9A to FIG. 9C are schematic cross-sectional view of around an upper surface 33 of the substrate W when the liquid film 40 is excluded from the substrate W in the case where the vapor layer 41 is formed in the liquid film excluding step.

As shown in FIG. 9A, in a state where the liquid film 40 of the low surface tension liquid such as the IPA is formed (T4 of FIG. 6), the IPA spreads to the bottom of the gap of the fine pattern 30 which is formed on the upper surface 33 of the substrate W. This state is maintained until depressurization of the inter space 7a is started (before step T7 of FIG. 6).

Then, when the internal space 7a is depressurized in the liquid film excluding step, a part of the liquid film 40 of the IPA on the upper surface 33 of the substrate W thereby evaporates and vaporizes before the pressure of the internal space 7a reaches the second pressure. As a result, a vapor of the IPA fills the gap of the fine pattern 30, and the liquid film 40 of the IPA floats from the surface of the substrate W (an upper surface 31a of each structure 31). As a result, as shown in FIG. 9B, the vapor layer 41 is formed between the substrate W and the liquid film 40.

Then, by continuing depressurization of the internal space 7a, as shown in FIG. 9, the IPA constituting the liquid film 40 evaporates and the liquid film 40 is eliminated from the substrate W.

As explained above, in the liquid film excluding step, by reducing the pressure of the internal space 7a until the pressure of the internal space 7a reaches the second pressure in a state where the temperature of the liquid film 40 reaches a temperature which is higher than the boiling point of the IPA at the second pressure (the atmospheric pressure), the liquid film 40 is excluded after passing through the vapor layer 41 is famed between the liquid film 40 and the substrate W.

According to this embodiment, in the case where the vapor layer 41 is formed in the heating step (see FIG. 8A to 8C), the substrate W is heated so as to reaches a high temperature (for example, the high temperature is about 10° C. to 100° C. higher than the boiling point (82.6° C.) of the IPA at the atmospheric pressure) in the heating step. Therefore, the IPA (the processing liquid) near the upper surface 33 of the substrate W instantaneously evaporates and the vapor layer 41 is formed. Therefore, compared to a method in which the liquid film 40 of the IPA is gradually evaporated from above, the time during which the surface tension acts on the upper surface 33 of the substrate W (each the structure 31 of the fine pattern 30 is formed on the upper surface) is shortened.

In depressurization of the internal space 7a in the liquid film excluding step, the pressure of the internal space 7a is brought to the second pressure, which is lower than the first pressure, in the state where the vapor layer 41 is maintained. The temperature of the liquid film 40 is higher than the boiling point (82.6° C.) of the IPA in a state where the pressure of the internal space 7a reaches the second pressure by depressurization. Therefore, the IPA is instantaneously evaporated, so that the liquid film 40 is instantaneously excluded from the substrate W.

As a result, in the case where the vapor layer 41 in the heating step, the liquid film 40 can be excellently removed from the substrate W.

According to this embodiment, in the case where the vapor layer 41 is formed in the liquid film excluding step (see FIG. 9A to 9C), in the liquid film excluding step, the liquid film 40 is excluded from the substrate W after passing through the state where the vapor layer 41 of the IPA is formed between the liquid film 40 and the substrate W, by reducing the pressure of the sealed internal space 7a. The temperature of the substrate W reaches a high temperature at which the vapor layer 41 is formed between the liquid film 40 and the substrate W during depressurization of the sealed internal space 7a. Therefore, the IPA near the upper surface 33 of the substrate W instantaneously evaporates, and the vapor layer 41 is foamed. Therefore, compared to the method in which the liquid film 40 of the IPA is gradually evaporated from above, the time during which the surface tension acts on the upper surface 33 of the substrate W (each the structure 31 of the fine pattern 30 is formed on the upper surface) is shortened.

In depressurization of the internal space 7a in the liquid film excluding step, the pressure of the internal space 7a is brought to the second pressure (the atmospheric pressure), which is lower than the first pressure, in a state where the temperature of the liquid film 40 is maintained at the temperature which is higher than the boiling point of the IPA at the second pressure. Therefore, the temperature of the liquid film 40 is the temperature which is higher than the boiling point at the second pressure (the atmospheric pressure), in a state where the pressure of the internal space 7a reaches the second pressure by depressurization. Therefore, the IPA instantaneously evaporates, so that the liquid film 40 is instantaneously excluded from the substrate W.

As a result, in the case where the vapor layer 41 is formed in the liquid film excluding step, the liquid film 40 can be excellently removed from the substrate W.

According to this embodiment, the second pressure is a pressure which is equal to the atmospheric pressure. Therefore, by a simple method of opening the internal space 7a to the outside of the internal space 7a, it is possible to discharge the gas in the internal space 7a to the outside of the internal space 7a (the gas discharging step) to reduce the internal space 7a. Therefore, in the liquid film excluding step, by reducing the pressure of the internal space 7a with the simple method, the IPA can instantaneously be evaporated.

Furthermore, the pressure in the internal space 7a of the sealed chamber 7, in a state where the liquid film 40 is eliminated from the substrate W, reaches the atmospheric pressure, so that the substrate W can be removed from the sealed chamber 7 without adjusting the pressure of the internal space 7a after depressurization of the internal space 7a.

Furthermore, since the second pressure is the pressure that is equal to the atmospheric pressure, the difference between the first pressure and the second pressure can be increased, as compared with a substrate processing in which the second pressure is set a pressure that is higher than the atmospheric pressure. In other words, compared to a configuration in which the second pressure is higher than the atmospheric pressure, the difference between the temperature of the liquid film 40 and the boiling point of the IPA after reducing the pressure of the internal space 7a to the second pressure. Therefore, an evaporation rate, at the time when the IPA evaporates, is increased by the depressurization of the internal space 7a. Therefore, in the liquid film excluding step, the IPA evaporates more instantaneously by depressurization of the internal space 7a, so that the liquid film 40 is excluded from the substrate W more instantaneously.

According to this embodiment, the pressurizing step and the heating step is executed in parallel. Therefore, the time, during which from when the substrate W is held by the substrate holding unit 5 to when the depressurization of the internal space 7a of the sealed chamber 7 is started, can be shortened. Therefore, the time required for substrate processing can be shortened.

According to this embodiment, the liquid film forming step and the pressurizing step is executed in parallel. Therefore, the time, during which from when the substrate W is held by the substrate holding unit 5 to when the depressurization of the internal space 7a of the sealed chamber 7 is started, can be shortened. Therefore, the time required for substrate processing can be shortened.

According to this embodiment, the heating step includes the contact heating step of heating the substrate in a state where a heater unit 6 is in contact with a lower surface of the substrate W. As a result, the substrate is heated efficiently, so that the time required for the heating step can be shortened. Therefore, the time, during which from when the substrate W is held by the substrate holding unit 5 to when the depressurization of the internal space 7a of the sealed chamber 7 is started, can be shortened. Therefore, the time required for substrate processing can be shortened.

Referring to FIG. 6, in the drying process (S4 of FIG. 5) of the substrate processing in this embodiment, step T1 to step T10 are executed in this order. However, unlike the drying process (S4 of FIG. 5) in the aforementioned embodiment, the order of step T2 to step T6 can be arbitrarily changed. However, in the heating step, the substrate W needs to be heated such that the temperature of the liquid film 40 does not exceed the boiling point of the processing liquid at the pressure of the internal space 7a. Thus, the pressurizing step, the heating step and the liquid film forming step can be started in an arbitrary order. Therefore, these steps can be executed sequentially, or these steps can be executed in parallel.

In the liquid film forming step of the drying process (S4 of FIG. 5) of the substrate processing in this embodiment, the liquid film 40 of the rinse liquid may be formed instead of the liquid film 40 of the low surface tension liquid. In this case, supply of the low surface tension liquid to the upper surface of the substrate W is not executed. That is, step T2 and step T4 of FIG. 6 are omitted. Instead, the liquid film 40 of the rinse liquid is formed on the substrate W by the rinse liquid such as DIW which is supplied from the rinse liquid nozzle 91 before the sealing step (before step T1 of FIG. 6). In this case, the rinse liquid supplying unit 9 functions as a processing liquid supplying unit which supplies processing liquid which processes the upper surface of the substrate W.

### Second Preferred Embodiment

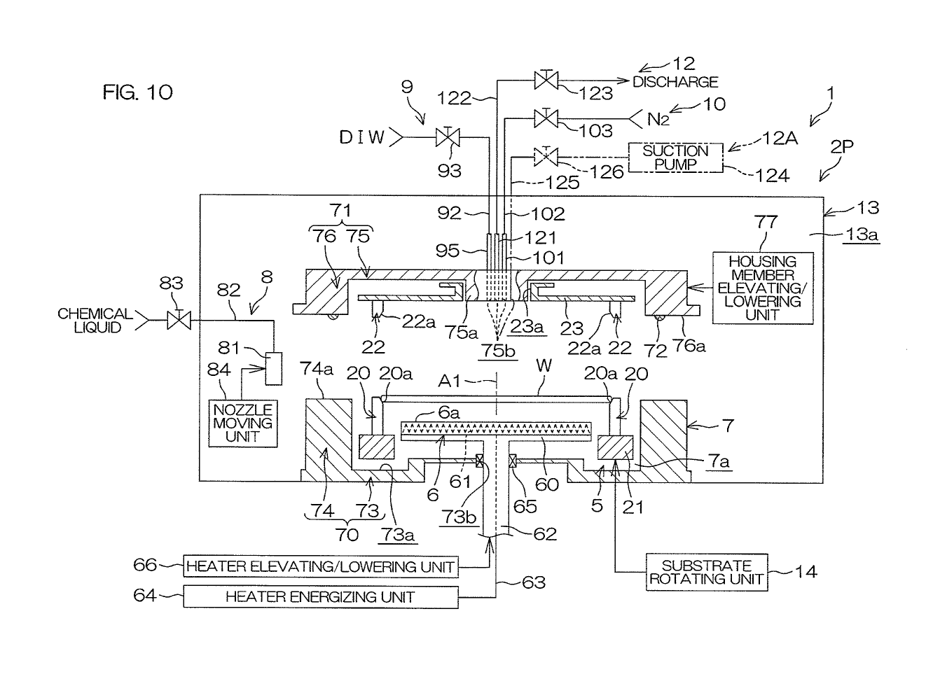

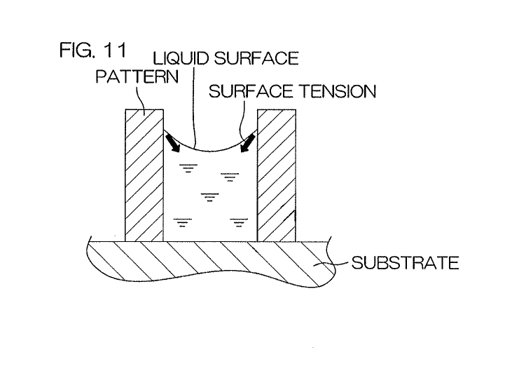

FIG. 10 is an illustrative partial cross-sectional view to explain a configuration example of a processing unit 2P which is included in the substrate processing apparatus 1 according to a second preferred embodiment of the present invention. In the second embodiment of FIG. 10, the same reference numerals are given to the same members as those described so far, and the description thereof is omitted.

In the processing unit 2P according to the second preferred embodiment, unlike the processing unit 2 according to the first preferred embodiment, the rinse liquid supplying unit 9 includes a rinse liquid nozzle 95 which is inserted through the insertion hole 75b which is provided in the central projection 75a of the bottom wall 75 of the upper side housing member 71, instead of the rinse liquid nozzle 91. The rinse liquid nozzle 95 is a fixed nozzle. The rinse liquid supply pipe 92 is connected to the rinse liquid nozzle 95. The processing unit 2P does not include the low surface tension liquid supplying unit 11.

In the substrate processing by the substrate processing apparatus 1 according to the second preferred embodiment, the DIW is supplied from the rinse liquid nozzle 95 to the upper surface of the rotational substrate W in the rinse process (S3 of FIG. 5). In the drying process (S4 of FIG. 5), the liquid film 40 of the rinse liquid such as DIW is formed on the substrate W (a liquid film forming step). Then, in the heating step or the liquid film excluding step, the vapor layer 41 of the rinse liquid is formed. Then, in the liquid film excluding step, the rinse liquid evaporates, so that the liquid film 40 of the rinse liquid is excluded. In the substrate processing of this embodiment, the rinse liquid supplying unit 9 functions as a processing liquid supplying unit which supplies the processing liquid which processes the upper surface of the substrate W.

Also in this embodiment, the same effect as that of the first embodiment is exerted.

The present invention is not limited to the embodiments described above, and can be implemented in still another embodiment.

For example, unlike the first preferred embodiment and the second preferred embodiment described above, referring the two-dot chain line in FIG. 3 and the two-dot chain line in FIG. 10, the processing unit 2, 2P may include a suction unit 12A sucks the gas in the internal space 7a.

The suction unit 12A includes a suction pump 124 such as a vacuum pump, a suction pipe 125 which is connected to the suction pump 124 and the internal space 7a, and a suction valve 126 which is interposed in the suction pipe 125. The tip of the suction pipe 125 is inserted in the insertion hole 75b which is provided in the central projection 75a of the bottom wall 75 of the upper side housing member 71.

the suction pump 124 is controlled by the controller 3 (see the two-dot chain line in FIG. 4). the suction valve 126 is opened and closed by the controller 3 (see FIG. 4). In the liquid film excluding step (the reducing pressure step) of the substrate process by the substrate processing apparatus 1 according to this modified example, the suction valve 126 is opened instead of the discharge valve 123, and the internal space 7a can thereby be depressurized such that the pressure of the internal space 7a reaches a pressure which is lower than the atmospheric pressure. That is, the second pressure can be made lower than the atmospheric pressure. Thus, the suction unit 12A functions as a pressure reducing unit which reduces the pressure of the sealed internal space 7a.

In this substrate process, the discharge valve 123 is opened after the reducing pressure step is finished and before the sealed chamber 7 is opened up and down. Thus, the pressure of the internal space 7a becomes equal to the atmospheric pressure, and the sealed chamber 7 can thereby be open up and down and the internal space 7a can thereby be opened to the outside (step T10).

According to this modified example, the second pressure can become a pressure which is lower than the atmospheric pressure. Therefore, compared to the substrate process in which the second pressure is set to a pressure which is equal to the atmospheric pressure (substrate Processing described with reference to FIGS. 5 to 9) and the substrate processing in which the second pressure is set to a pressure which is higher than the atmospheric pressure, the difference between the first pressure and the second pressure can be further increased. In other words, compared to the substrate process in which the second pressure is set to a pressure which is equal to the atmospheric pressure (substrate Processing described with reference to FIGS. 5 to 9) and the substrate processing in which the second pressure is set to a pressure which is higher than the atmospheric pressure, the difference between the temperature of the liquid film 40 and the boiling point of the IPA after reducing the pressure of the internal space 7a to the second pressure can be increased.

Therefore, evaporation rate at the time, when the IPA evaporates, is increased by depressurization of the internal space 7a. As a result, in the liquid film excluding step, the IPA further instantaneously evaporates by depressurization of the internal space 7a, so that the liquid film 40 is excluded from the substrate W further instantaneously.

Also, in the substrate processing of the embodiment to be described above, the second pressure may be a pressure which is lower than the first pressure and higher than the atmospheric pressure. To do so, in the liquid film excluding step, it is necessary to close the discharge valve 123 or the suction valve 126 before the pressure of the internal space 7a reaches the atmospheric pressure or less.

The present application corresponds to Japanese Patent Application No. 2017-003512 filed on Jan. 12, 2017 in the Japan Patent Office, and the entire disclosure of the present application is incorporated herein by reference.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A substrate processing method comprising:
a substrate holding step that a substrate is held by a substrate holding unit that holds the substrate horizontally;
a sealing step of sealing an internal space of a chamber in a state where the substrate holding unit that holds the substrate is housed in the internal space of the chamber;
a liquid film forming step of forming a liquid film of processing liquid, which processes an upper surface of the substrate, by supplying the processing liquid to the upper surface of the substrate which is held horizontally;
a pressurizing step of pressurizing the internal space until a pressure of the internal space reaches a first pressure which is higher than an atmospheric pressure, by supplying a gas to the internal space;
a heating step of heating the substrate such that a vapor layer of processing liquid is formed between the liquid film and the substrate in a state where the pressure of the internal space reaches the first pressure; and
a liquid film excluding step of excluding the liquid film from the substrate by evaporating the processing liquid, by reducing the pressure of the internal space until the pressure of the internal space reaches a second pressure, which is lower than the first pressure, while keeping a state where the vapor layer of the processing liquid between the liquid film and the substrate is formed.

2. The substrate processing method according to claim 1, wherein the second pressure is equal to or lower than the atmospheric pressure.

3. The substrate processing method according to claim 1, wherein the second pressure is equal to the atmospheric pressure, and
the liquid film excluding step includes a gas discharging step of discharging the gas in the internal space to the outside of the internal space by opening the internal space to the outside of the internal space, in order to reduce the pressure of the internal space.

4. The substrate processing method according to claim 1, wherein the pressurizing step and the heating step are performed in parallel.

5. The substrate processing method according to claim 1, wherein the liquid film forming step and the pressurizing step are performed in parallel.

6. The substrate processing method according to claim 1, wherein the heating step includes a contact heating step of heating the substrate in a state where a heater unit is in contact with a lower surface of the substrate.

7. A substrate processing method comprising:
a substrate holding step that a substrate is held by a substrate holding unit that holds the substrate horizontally;
a sealing step of sealing an internal space of a chamber in a state where the substrate holding unit that holds the substrate is housed in the internal space of the chamber;
a liquid film forming step of forming a liquid film of processing liquid, which processes an upper surface of the substrate, by supplying the processing liquid to the upper surface of the substrate which is held horizontally;
a pressurizing step of pressurizing the internal space until a pressure of the internal space reaches a first pressure which is higher than an atmospheric pressure, by supplying a gas to the internal space;
a heating step of heating the substrate such that the temperature of the liquid film reaches a temperature which is higher than a boiling point of the processing liquid at the atmospheric pressure in a state where the pressure of the internal space reaches the first pressure; and
a liquid film excluding step of excluding the liquid film from the substrate by evaporating the processing liquid so as to pass through a state where the vapor layer of the processing liquid between the liquid film and the substrate is formed, by reducing the pressure of the internal space until the pressure of the internal space reaches a second pressure, which is lower than the first pressure, while keeping a state where the temperature of the liquid film reaches the boiling point of the processing liquid at the atmospheric pressure.

8. The substrate processing method according to claim 7, wherein the second pressure is equal to or lower than the atmospheric pressure.

9. The substrate processing method according to claim 7, wherein the second pressure is equal to the atmospheric pressure, and
the liquid film excluding step includes a gas discharging step of discharging the gas in the internal space to the outside of the internal space by opening the internal space to the outside of the internal space, in order to reduce the pressure of the internal space.

10. The substrate processing method according to claim 7, wherein the pressurizing step and the heating step are performed in parallel.

11. The substrate processing method according to claim 7, wherein the liquid film forming step and the pressurizing step are performed in parallel.

12. The substrate processing method according to claim 7, wherein the heating step includes a contact heating step of heating the substrate in a state where a heater unit is in contact with a lower surface of the substrate.

13. A substrate processing apparatus comprising:
a substrate holding unit that holds a substrate horizontally;
a chamber that has an internal space which houses the substrate holding unit;
a processing liquid supplying unit that supplies a processing liquid, which processes an upper surface of the substrate, to the upper surface of the substrate which is held horizontally;
a heater unit that heats the substrate;
a gas supplying unit that supplies a gas to the internal space;
a reducing pressure unit that reduces a pressure of the internal space; and
a controller that controls the substrate holding unit, the chamber, the processing liquid supplying unit, the heater unit, the gas supplying unit and the reducing pressure unit,
wherein the controller is programed to perform a substrate holding step that the substrate is held by the substrate holding unit, a sealing step of sealing the internal space in a state of housing the substrate holding unit, a liquid film forming step of forming the liquid film of the processing liquid on the substrate by supplying the processing liquid to the upper surface of the substrate, a pressurizing step of pressurizing the internal space until the pressure of the internal space reaches a first pressure which is higher than an atmospheric pressure, by supplying the gas to the internal space, a heating step of heating the substrate such that a vapor layer of the processing liquid is formed between the liquid film and the substrate in a state where the pressure of the internal space reaches the first pressure, and a liquid film excluding step of excluding the liquid film from the substrate by evaporating the processing liquid, by reducing the pressure of the internal space until the pressure of the internal space reaches a second pressure, which is lower than the first pressure, while keeping a state where the vapor layer of the processing liquid between the liquid film and the substrate is formed.

14. A substrate processing apparatus comprising:
a substrate holding unit that holds a substrate horizontally;
a chamber that has an internal space which houses the substrate holding unit;
a processing liquid supplying unit that supplies a processing liquid, which processes an upper surface of the substrate, to the upper surface of the substrate which is held horizontally;
a heater unit that heats the substrate;
a gas supplying unit that supplies a gas to the internal space;
a reducing pressure unit that reduces a pressure of the internal space; and
a controller that controls the substrate holding unit, the chamber, the processing liquid supplying unit, the heater unit, the gas supplying unit and the reducing pressure unit,
wherein the controller is programed to perform a substrate holding step that the substrate is held by the substrate holding unit, a sealing step of sealing the internal space in a state of housing the substrate holding unit, a liquid film forming step of forming the liquid film of the processing liquid on the substrate by supplying the processing liquid to the upper surface of the substrate, a pressurizing step of pressurizing the internal space until the pressure of the internal space reaches a first pressure which is higher than an atmospheric pressure, by supplying the gas to the internal space, a heating step of heating the substrate such that the temperature of the liquid film reaches a temperature which is higher than a boiling point of the processing liquid at the atmospheric pressure in a state where the pressure of the internal space reaches the first pressure, and a liquid film excluding step of excluding the liquid film from the substrate by evaporating the processing liquid so as to pass through a state where the vapor layer of the processing liquid between the liquid film and the substrate is formed, by reducing the pressure of the internal space until the pressure of the internal space reaches a second pressure, which is lower than the first pressure, while keeping a state where the temperature of the liquid film reaches the boiling point of the processing liquid at the atmospheric pressure.

15. The substrate processing apparatus according to claim 13, wherein the second pressure is equal to or lower than the atmospheric pressure.

16. The substrate processing apparatus according to claim 13, wherein the second pressure is equal to the atmospheric pressure,
the reducing pressure unit includes an discharging unit that discharges the gas in the internal space to the outside of the internal space by opening the internal space to the outside of the internal space, and
the controller is programed to perform a gas discharging step of discharging the gas in the internal space to the outside of the internal space in order to reduce the pressure of the internal space by controlling the discharging unit.

17. The substrate processing apparatus according to claim 13, wherein the controller is programed to perform the pressurizing step and the heating step in parallel.

18. The substrate processing apparatus according to claim 13, wherein the controller is programed to perform the liquid film forming step and the pressurizing step in parallel.

19. The substrate processing apparatus according to claim 13, further comprising a heater elevating/lowering unit that elevates and lowers the heater,
wherein the controller is programed to perform a contact heating step of heating the substrate in a state where the heater unit is in contact with a lower surface of the substrate by controlling the heater elevating/lowering unit.
